(19) United States
(12) Patent Application Publication
(10) Pub. No.: US 2023/0003785 A1
(43) Pub. Date: Jan. 5, 2023

(54) Method and Apparatus for Sensor Measurements Processing

(71) Applicant: Siemens Aktiengesellschaft, München (DE)

(72) Inventors: Cheng Feng, Hangzhou (CN); Xiao Liang, Beijing (CN); Daniel Schneegaß, München (DE); Peng Wei Tian, Beijing (CN)

(73) Assignee: Siemens Aktiengesellschaft, München (DE)

(21) Appl. No.: 17/781,508

(22) PCT Filed: Dec. 2, 2019
(86) PCT No.: PCT/CN2019/122465

§ 371 Date: Jun. 1, 2022

(51) Int. Cl. G01R 31/08

(52) U.S. Cl. CPC G01R 31/088

(57) ABSTRACT

Various embodiments of the teachings herein include methods, apparatuses, and computer-readable storage media for sensor measurements processing. An example method 100 includes: getting (S101) measurements by a group of sensors; estimating (S102) initial true states of the physical processes; and repeating the following until convergence: calculating (S103) reliability scores of the group of sensors such that a more reliable sensor should be more likely to provide measurements which are closer to real state of the physical process monitored by the sensor; and estimating (S104), based on the calculated reliability scores, true states of the physical processes, such that the real state of a physical process should be closer to measurements by a more reliable sensor.

### TECHNICAL FIELD

The present disclosure relates to industrial technology. Various embodiments of the teachings herein include methods, apparatuses, and computer-readable storage media for sensor measurement processing.

### BACKGROUND

With the trend of Internet of things, sensors are becoming pervasive. The measurements from sensors have become an important source of knowledge for decision making for either human-beings or machines. Sometimes, measurements from sensors can be error-prone due to a lot of reasons such as equipment noises, faults, aging, extreme ambient environment conditions, etc.

To improve accuracy, sensor measurement fusion can be done to combine measurements from multiple sensors. Typical fusion methods combine measurements from multiple sensors using weighted averaging. For example, Kalman filtering-based methods (C. K. Chui, G. Chen et al., Kalman filtering. Springer, 2017) assign different weights to sensors based on their noise covariance. However, Kalman filtering-based methods require the dynamic model of the underlying physical process to be known, which significantly limits their applicability in many practical scenarios.

### SUMMARY

The teachings of the present disclosure include methods, apparatuses, and computer-readable storage media for sensor measurement processing. For example, some embodiments of the teachings herein include a method (100) for sensor measurements processing, comprising: getting (S101), measurements by a group of sensors, wherein different sensors monitor different physical processes; estimating (S102), based on the measurements, initial true states of the physical processes; repeating following steps until convergence: calculating (S103), based on the estimated true states of the physical processes, reliability scores of the group of sensors wherein the higher the score is, the more reliable a sensor is, such that a more reliable sensor should be more likely to provide measurements which are closer to real state of the physical process monitored by the sensor; estimating (S104), based on the calculated reliability scores, true states of the physical processes, such that the real state of a physical process should be closer to measurements by a more reliable sensor.

In some embodiments, the method includes, before repeating until convergence, constructing (S102′), for each of the physical processes, at least one soft sensor by calculating measurement by a soft sensor based on measurement by at least one sensor other than the sensor monitoring the physical process in the group of sensors, to enlarge the group of sensors.

In some embodiments, calculating (S103) reliability scores of the group of sensors comprises calculating reliability scores of the group of sensors, such that the more reliable a sensor is, the higher penalty if the measurement by the sensor is far away from the estimated true state of the respective physical process.

In some embodiments, calculating (S103) reliability scores of the group of sensors comprises calculating out reliability scores of the group of sensors which make sum of sensor reliability-weighted distance between estimated true state of a physical process and measurement by the sensor monitoring the physical process in predefined at least one time step and among the physical processes and among the group of sensors is minimum.

In some embodiments, estimating (S104) true states of physical processes monitored by the group of sensors comprises calculating out true states of the physical processes which make sum of sensor reliability-weighted distance between estimated true state of a physical process and measurement by the sensor monitoring the physical process in predefined at least one time step and among the physical processes and among the group of sensors is minimum.

In some embodiments, estimating (S104) true states of the physical processes comprises estimating true states of the physical processes such that estimated true states of the physical processes monitored by the group of sensors in two consecutive discrete time steps are smooth.

As another example, some embodiments include a method (200) for sensor measurements processing comprising: getting (S201), measurements by a group of sensors, wherein different sensors monitor different physical processes; acquiring (S202) reliability scores of the group of sensors; conducting sensor fusion (S203), based on the acquired reliability scores, to estimate true states of the physical processes monitored by the group of sensors such that a true state of a physical process should be closer to the measurements by sensors with higher reliability scores.

In some embodiments, conducting sensor fusion (S203), based on the acquired reliability scores, to estimate true states of the physical processes monitored by the group of sensors comprises conducting sensor fusion (S203) such that estimated true states of the physical processes monitored by the group of sensors in two consecutive discrete time steps are smooth.

In some embodiments, getting (S201) measurements by a group of sensors comprises: getting at time step t, measurements by the group of sensors; acquiring (S202) reliability scores of the group of sensors comprises: calculating reliability scores of the group of sensors based on: measurements by the group of sensors got at each time step from t−L to t, and estimated true states of the physical processes at each time step from t−L to t.

In some embodiments, before estimating (S203), based on the acquired reliability scores, true states of the physical processes monitored by the group of sensors, the method includes constructing (S202′), for each physical process, at least one soft sensor by calculating measurement by a soft sensor based on measurement by at least one sensor other than the sensor monitoring the physical process in the group of sensors, to enlarge the group of sensors.

As another example, some embodiments include an apparatus (300) for sensor measurements processing, comprising: a measurement module (301), configured to get measurements by a group of sensors, wherein different sensors monitor different physical processes; an estimation module (302), configured to estimate based on the measurements, initial true states of the physical processes monitored by the group of sensors; a calculation module (303), configured to repeat following steps until convergence: calculate, based on the estimated true states of the physical processes, reliability scores of the group of sensors wherein the higher the score is, the more reliable a sensor is, such that a more reliable sensor should be more likely to provide measurements which are closer to real state of the physical process monitored by the sensor; estimate, based on the calculated reliability scores, true states of the physical processes, such that the real state of a physical process should be closer to measurements by a more reliable sensor.

In some embodiments, there is a construction module (304), configured to, before the calculation module (303) repeats until convergence, construct, for each of the physical processes, at least one soft sensor by calculating measurement by a soft sensor based on measurement by at least one sensor other than the sensor monitoring the physical process in the group of sensors, to enlarge the group of sensors.

In some embodiments, the calculation module (303) is further configured to calculate reliability scores of the group of sensors, such that the more reliable a sensor is, the higher penalty if the measurement by the sensor is far away from the estimated true state of the respective physical process.

In some embodiments, the calculation module (303) is further configured to calculate out reliability scores of the group of sensors which make sum of differences between estimated true state of a physical process and measurement by the sensor monitoring the physical process in predefined at least one time step and among the physical processes and among the group of sensors is minimum.

In some embodiments, the calculation module (303) is further configured to calculate out true states of the physical processes which make sum of differences between estimated true state of a physical process and measurement by the sensor monitoring the physical process in predefined at least one time step and among the physical processes and among the group of sensors is minimum.

In some embodiments, the calculation module (303) is further configured to estimate true states of the physical processes such that estimated true states of the physical processes monitored by the group of sensors in two consecutive discrete time steps are smooth.

As another example, some embodiments include an apparatus (300) for sensor measurements processing, comprising: at least one memory (305), configured to store instructions; and at least one processor (306), coupled to the at least one memory (305), and upon execution of the executable instructions, configured to execute one or more of the methods described herein.

As another example, some embodiments include an apparatus (400) for sensor measurements processing, comprising: a measurement module (401), configured to get measurements by a group of sensors, wherein different sensors monitor different physical processes; an acquisition module (402), configured to acquire reliability scores of the group of sensors; an fusion module (403), configured to estimate, based on the acquired reliability scores, true states of the physical processes monitored by the group of sensors such that a true state of a physical process should be closer to the measurements by sensors with higher reliability scores.

In some embodiments, the fusion module (403) is further configured to conduct the sensor fusion such that estimated true states of the physical processes monitored by the group of sensors in two consecutive discrete time steps are smooth.

In some embodiments, the measurement module (401) is further configured to get at time step t, measurements by a group of sensors; the acquisition module (402) is further configured to calculate reliability scores of the group of sensors based on: measurements by the group of sensors got at each time step from t−L to t, and estimated true states of the physical at each time step from t−L to t.

In some embodiments, there is a construction module (404), configured to, before the acquisition module (402) acquires reliability scores of the group of sensors, construct, for each physical process, at least one soft sensor by calculating measurement by a soft sensor based on measurement by at least one sensor other than the sensor monitoring the physical process in the group of sensors, to enlarge the group of sensors.

As another example, some embodiments include an apparatus (400) for sensor measurements processing, comprising: at least one memory (405), configured to store instructions; and at least one processor (406), coupled to the at least one memory (305), and upon execution of the executable instructions, configured to execute one or more of the methods as described herein.

As another example, some embodiments include a computer-readable medium, storing executable instructions, which upon execution by a processor, enables the processor to execute one or more of the methods as described herein.

### BRIEF DESCRIPTION OF THE DRAWINGS

The above mentioned attributes and other features and advantages of the present technique and the manner of attaining them will become more apparent and the present technique itself will be better understood by reference to the following description of embodiments of the present technique taken in conjunction with the accompanying drawings, wherein:

FIG. 1 is a flow chart showing an example method for sensor measurement processing incorporating teachings of the present disclosure;

FIG. 2 is a flow chart showing an example method for sensor measurement processing incorporating teachings of the present disclosure;

FIG. 3 and FIG. 4 are block diagrams representing apparatuses for sensor measurement processing incorporating teachings of the present disclosure;

FIG. 5 and FIG. 6 are block diagrams representing apparatuses for sensor measurement processing incorporating teachings of the present disclosure; and

FIG. 7 and FIG. 8 depict experimental results of various aspects of the present disclosure.

### DETAILED DESCRIPTION

Based on sensor measurements, reliability scores of sensors can be calculated. By giving less weight to unreliable sensors, accuracy of estimation of true states of monitored physical processes can be improved. In comparison to Kalman filtering-based methods, the dynamic model of the underlying physical process is not necessarily known to conduct measurement fusion.

In some embodiments, a method for sensor measurements processing is presented to calculate reliability scores of sensors. The method includes following steps: getting measurements by a group of sensors, wherein different sensors monitor different physical processes; estimating, based on the measurements, initial true states of the physical processes; and repeating the following steps until convergence: calculating, based on the estimated true states of the physical processes, reliability scores of the group of sensors wherein the higher the score is, the more reliable a sensor is, such that a more reliable sensor should be more likely to provide measurements which are closer to real state of the physical process monitored by the sensor; and estimating, based on the calculated reliability scores, true states of the physical processes, such that the real state of a physical process should be closer to measurements by a more reliable sensor.

In some embodiments, an apparatus for sensor measurements processing acquires more precise evaluation of true states of physical processes. The apparatus comprises: a measurement module, configured to get measurements by a group of sensors, wherein different sensors monitor different physical processes; an estimation module, configured to estimate based on the measurements, initial true states of the physical processes monitored by the group of sensors; and a calculation module, configured to repeat following steps until convergence: calculate, based on the estimated true states of the physical processes, reliability scores of the group of sensors wherein the higher the score is, the more reliable a sensor is, such that a more reliable sensor should be more likely to provide measurements which are closer to real state of the physical process monitored by the sensor; and estimate, based on the calculated reliability scores, true states of the physical processes, such that the real state of a physical process should be closer to measurements by a more reliable sensor.

In some embodiments, the apparatus includes: at least one memory, configured to store instructions; and at least one processor, coupled to the at least one memory, and upon execution of the executable instructions, configured to execute one or more of the methods described in the present disclosure.

In some embodiments, a computer-readable medium stores executable instructions, which upon execution by a processor, enables the processor to execute one or more of the methods described in the present disclosure.

By combination of sensor reliability evaluation and sensor measurements fusion, calculation of reliability scores of sensors and sensor fusion are processed as an optimization problem, which does not necessarily need any Kalman filtering-based algorithms. As a result, our solution is more generalizable as it does not assume dynamic model of the underlying physical process to be known, which makes our solution much more applicable in practical scenarios. And reliability scores of sensors can provide an important metric for benchmarking between different sensor vendors. By monitoring sensor reliability, predictive maintenance of sensor systems can be conducted by timely identifying and replacing unreliable sensors.

In some embodiments, before repeating until convergence, for each of the physical processes, at least one soft sensor can be constructed by calculating measurement by a soft sensor based on measurement by at least one sensor other than the sensor monitoring the physical process in the group of sensors, to enlarge the group of sensors. With construction of soft sensors, rich information for evaluation of the true states of physical processes can be got by utilizing correlation between the states of multiple physical processes, to enhance the inference of sensor reliability scores and the estimation of truth states of physical processes.

In some embodiments, reliability scores of the group of sensors can be calculated such that the more reliable a sensor is, the higher penalty if the measurement by the sensor is far away from the estimated true state of the respective physical process.

In some embodiments, reliability scores of the group of sensors can be calculated out which make sum of sensor reliability-weighted distance between estimated true state of a physical process and measurement by the sensor monitoring the physical process in predefined at least one time step and among the physical processes and among the group of sensors is minimum.

In some embodiments, true states of the physical processes can be calculated out which make sum of sensor reliability-weighted distance between estimated true state of a physical process and measurement by the sensor monitoring the physical process in predefined at least one time step and among the physical processes and among the group of sensors is minimum.

In some embodiments, true states of the physical processes can be calculated such that estimated true states of the physical processes monitored by the group of sensors in two consecutive discrete time steps are smooth. With the smoothing processing, unexpected fluctuation of true states of the physical processes can be avoided.

In some embodiments, a method for sensor measurement processing includes: getting, measurements by a group of sensors, wherein different sensors monitor different physical processes; acquiring reliability scores of the group of sensors; and conducting sensor fusion, based on the acquired reliability scores, to estimate true states of the physical processes monitored by the group of sensors such that a true state of a physical process should be closer to the measurements by sensors with higher reliability scores.

In some embodiments, an apparatus for sensor measurement processing includes: a measurement module, configured to get measurements by a group of sensors, wherein different sensors monitor different physical processes; an acquisition module, configured to acquire reliability scores of the group of sensors; and a fusion module, configured to estimate, based on the acquired reliability scores, true states of the physical processes monitored by the group of sensors such that a true state of a physical process should be closer to the measurements by sensors with higher reliability scores.

In some embodiments, an apparatus for sensor measurement processing includes: at least one memory, configured to store instructions; and at least one processor, coupled to the at least one memory, and upon execution of the executable instructions, configured to execute one or more of the methods described in the present disclosure.

In some embodiments, a computer-readable medium stores executable instructions, which upon execution by a processor, enables the processor to execute one or more of the methods described in the present disclosure.

The embodiments described provide an efficient approach for real-time sensor fusion and reliability score calculation is provided, with which real-time sensor fusion and reliability monitoring can be conducted. In some embodiments, the sensor fusion can be conducted such that estimated true states of the physical processes monitored by the group of sensors in two consecutive discrete time steps are smooth. With the smoothing processing, unexpected fluctuation of true states of the physical processes can be avoided.

In some embodiments, measurements by the group of sensors can be got at time step t, then reliability scores of the group of sensors can be got by calculating reliability scores of the group of sensors based on: measurements by the group of sensors got at each time step from t−L to t, and estimated true states of the physical processes at each time step from t−L to t. In the sliding window with length L, the reliability score of sensors can be calculated and dynamically updated based on the sensor measurements observed and the fused results during the sliding window to make sure of accuracy.

In some embodiments, before estimating true states of the physical processes monitored by the group of sensors, for each physical process, at least one soft sensor can be constructed by calculating measurement by a soft sensor based on measurement by at least one sensor other than the sensor monitoring the physical process in the group of sensors, to enlarge the group of sensors. With construction of soft sensors, rich information for evaluation of the true states of physical processes can be got by utilizing correlation between the states of multiple physical processes, to enhance the inference of estimation of truth states of physical processes.

Reference Numbers:
100, 200: methods for sensor measurements processing
300, 400: apparatuses for sensor measurements processing
S101˜S104, S201˜S203: steps of methods for sensor measurements
processing
301˜304: modules of apparatus 300 for sensor measurements
processing
401˜404: modules of apparatus 400 for sensor measurements
processing
305, 405: at least one memory
306, 406: at least one processor
307, 407: I/O interfaces

### EXAMPLE EMBODIMENTS

Hereinafter, above-mentioned and other features of the present technique are described in details. Various embodiments are described with reference to the drawing, where like reference numerals are used to refer to like elements throughout. In the following description, for purpose of explanation, numerous specific details are set forth in order to provide a thorough understanding of one or more embodiments. It may be noted that the illustrated embodiments are intended to explain, and not to limit the scope of the disclosure. It may be evident that such embodiments may be practiced without these specific details.

When introducing elements of various embodiments of the present disclosure, the articles “a”, “an”, “the” and “said” are intended to mean that there are one or more of the elements. The terms “comprising”, “including” and “having” are intended to be inclusive and mean that there may be additional elements other than the listed elements.

To solve the above-mentioned problem of inaccurate measurements by sensors, reliability score of sensors are calculated to indicate reliability of a sensor, a sensor with higher reliability score, the measurement it provided is much closer to true state of a physical process it monitored. By giving less weight to unreliable sensors, accuracy of estimation of true states of monitored physical processes can be improved. With combination of sensor reliability evaluation and sensor measurements fusion, calculation of reliability scores of sensors and sensor fusion are processed as an optimization problem, which does not necessarily need any Kalman filtering-based algorithms. As a result, our solution is more generalizable as it does not assume dynamic model of the underlying physical process to be known, which makes our solution much more applicable in practical scenarios.

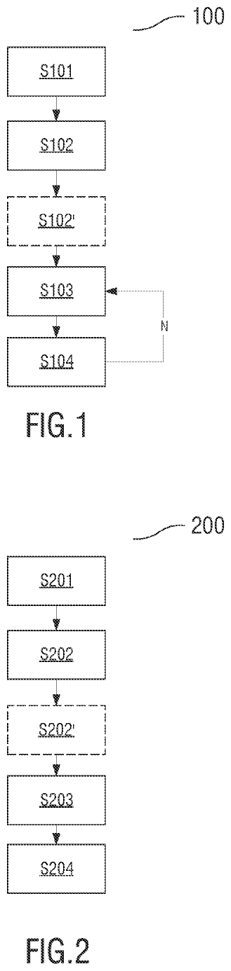

What's more, reliability scores of sensors can provide an important metric for benchmarking between different sensor vendors. And by monitoring sensor reliability, predictive maintenance of sensor systems can be conducted by timely identifying and replacing unreliable sensors. Two processes are introduced here, including the warm-up period and the real-time evaluation period. In the warm-up period, calculation of reliability scores of a group of sensors and true states of physical processes monitored by the group of sensors are initialized by solving a joint optimization problem (referring to FIG. 1 and method 100 of the present disclosure). In the real-time evaluation period, the reliability scores of the group of sensors can be updated and sensor measurements fusion is done by using simple closed form expressions (referring to FIG. 2 and method 200).

Here, considering the general case where there are a group of sensors monitoring multiple physical processes in a system. The system can be an industrial system, such as a factory or a production line, or an agriculture system, such as a farm, etc. Sensors are deployed in the system, including but not limited to temperature, pressure, humidity, flow, location sensors. They are deployed to monitor state of the physical process of the system. With the measurements provided by the sensors, true state of the physical process(es) can be estimated.

Let P be the set of physical processes, S be the set of sensors in the system, Sp denote the set of sensors that are monitoring the physical process p, where p∈P, |Sp|≥1 and Σ_{p∈P}|Sₚ|=|S|. That is to say, each physical process is monitored by one or more sensors, and each sensor can only monitor one physical process.

Let x^{t}=[x₁^{t}, x₂^{t}, . . . , x_{|S|}^{t}] be the monitored signals from the sensors (i.e. the measurements by the sensors) at a given discrete time t, where the timestamps t=1:T are a totally ordered set. Our target is to infer c^{t}=[c₁^{t}, c₂^{t}, . . . , c_{|S|}^{t}] and z^{t}=[z₁^{t}, z₂^{t}, . . . , z_{|P|}^{t}], which are the quantified reliability score of sensors and the real states of the underlying physical processes at time t, respectively. Here, we assume the underlying dynamic model of the physical processes is unknown to the user.

Now, referring to FIG. 1 to FIG. 8, details of implementations are described.

### Procedures

### The Warm-Up Period

Now, referring to FIG. 1, a method 100 of sensor measurement processing is before real-time evaluation of sensor reliability and information fusion can be conducted, so we call it a “warm-up period”. Assume the warm-up period lasts for T time steps. Here, the reliability score of each sensor is assumed to be fixed during the warm-up period, then c=[c₁, c₂, . . . , c_{|S|}] is used to denote the reliability scores of sensors at the warm-up period.

S101: measurements collection. In the step of S101, measurements by the above-mentioned group of sensors are got.

S102: initialization. In the step of S102, initial true states of the physical processes of the system are estimated based on the measurements got in the step S101.

Let

$${z}_{p}^{t} = \frac{1}{\vert {S}_{p} \vert} {\sum }_{s ∈ {S}_{p}} {x}_{s}^{t} ,$$

which means that we initialize the estimation of the true process states at the warm-up period as the mean value of the measurements from all sensors. Note that the estimation will be updated in the later steps.

S102′: soft sensor construction. Step S102′ is optional. In the step of S103, for each of the physical processes at least one soft sensor is constructed, by calculating measurement by a soft sensor based on measurement by at least one sensor other than the sensor monitoring the physical process in the group of sensors (here, we call them “explanatory sensors”), to enlarge the group of sensors. Taking a factory as an example, some physical process is monitored by many sensors, which can provide rich information of measurements to evaluation the true state of the physical process. But for a physical process monitored by less sensors, sometimes, measurement may be not enough to evaluate the true states, especially when the monitoring sensor(s) is/are not reliable. So here for each physical process, soft sensors are constructed, by utilizing correlation between the states of multiple physical processes to enhance the inference of sensor reliability scores and the estimation of truth states of physical processes. For each physical process, besides physical sensors, we further construct M soft sensors for monitoring its state at each time step. To be mentioned that, for different physical processes, different number of soft sensors can be constructed. optionally, the soft sensors can be constructed by random local linear regression. Local linear regression models are globally nonlinear, can achieve the requested accuracy and can be promptly adapted when the process characteristics change.

In some embodiments, when constructing a soft sensor, we select random subsets of sensors for explanatory variables to setup the local linear regression model. The reason we choose to do so is: a group of “weak learners” can come together to form a “strong learner”; and combining predictions from multiple models in ensembles works better if the predictions from the sub-models are uncorrelated or at best weakly correlated.

Concretely, let p be target physical process, t be current time step, to build up a soft sensor for p, we first randomly select ceiling (r*|S\Sp|) explanatory sensors from sensor set S\Sp, where r∈[0,1] is a tunable ratio. Let S_{p,m}^{t} be selected sensors for making a soft sensor m for process p at time t, x_{p,m}^{t} be the vector consists of the sensor signals from the selected sensors, we define a neighbour set J_{p,m}^{t} for the point x_{p,m}^{t}. The neighbor set is derived by the K-nearest neighbors using Euclidean distance, given a set of measurement points.

Then the signal of the soft sensor is given by:

$${y}_{p , m}^{t} = {w}_{p , m}^{t} {x}_{p , m}^{t} + {w}_{p , m , 0}^{t} = {\sum }_{s ∈ {S}_{p , m}^{t}} {w}_{p , m , s}^{t} {x}_{s}^{t} + {w}_{p , m , 0}^{t}$$

$$Where$$

$${w}_{p , m}^{t} , {w}_{p , m , 0}^{t} = {min}_{{w}_{p , m}^{t} , {w}_{p , m , 0}^{t}} {\sum }_{{x}_{{s}_{p , m}^{t}}^{{t}^{′}} ∈ {J}_{p , m}^{t}} {( {z}_{p}^{{t}^{′}} - {w}_{p , m}^{t} {x}_{{S}_{p , m}^{t}}^{{t}^{′}} - {w}_{p , m , 0}^{t} )}^{2}$$

S103: calculate reliability score of the group of sensors. In the step S103, reliability scores of the group of sensors are calculated based on the estimated true states of the physical processes, such that a more reliable sensor should be more likely to provide measurements which are closer to real state of the physical process monitored by the sensor.

Since we assume that reliability score of a sensor at the warm-up period is fixed, thus given the estimated values of the process state, we can obtain the reliability scores for the group of sensors at the warm-up period. Optionally, we can calculate out reliability scores of the group of sensors which make sum of sensor reliability-weighted distance between estimated true state of a physical process and measurement by the sensor monitoring the physical process in predefined at least one time step and among the physical processes and among the group of sensors is minimum.

In some embodiments, the reliability scores for the group of sensors can be calculated by solving the following constrained optimization problem:

$${min}_{c} {\sum }_{p ∈ P} {\sum }_{s ∈ {S}_{p}} {c}_{s} {\sum }_{t = 1}^{T} {( {z}_{p}^{t} - {x}_{s}^{t} )}^{2} + {\sum }_{p ∈ P} {\sum }_{m = 1}^{M} {\sum }_{t = 1}^{T} ( 1 - {e}_{p , m}^{t} ) \frac{{\sum }_{s ∈ {S}_{p , m}^{t}} \vert {w}_{p , m , s}^{t} \vert {c}_{s}}{{\sum }_{s ∈ {S}_{p , m}^{t}} \vert {w}_{p , m , s}^{t} \vert} {( {z}_{p}^{t} - {y}_{p , m}^{t} )}^{2} s . t . {\sum }_{s ∈ S} exp ( - {c}_{s} ) = 1 \qquad ( 1 )$$

Where e_{p,m}^{t}∈[0,1] is the normalized training error when fitting the mth soft sensor for process p at time t;

$$( 1 - {e}_{p , m}^{t} ) \frac{{\sum }_{s ∈ {S}_{p , m}^{t}} \vert {w}_{p , m , s}^{t} \vert {c}_{s}}{{\sum }_{s ∈ {S}_{p , m}^{t}} \vert {w}_{p , m , s}^{t} \vert}$$

works as the reliability score of the mth soft sensor for process p at time t, which indicates that the reliability score of a soft sensor is the weighted sum of the reliability scores of the explanatory sensors, scaled by the normalized training error when fitting the soft sensor (larger training error, smaller reliability score).

Here, in equation (1), soft sensors are taken into account. If not, the constrained optimization problem can be transformed into:

$${min}_{c} {\sum }_{p ∈ P} {\sum }_{s ∈ {S}_{p}} {c}_{s} {\sum }_{t = 1}^{T} {( {z}_{p}^{t} - {x}_{s}^{t} )}^{2} s . t . {\sum }_{s ∈ S} exp ( - {c}_{s} ) = 1 \qquad ( {1}^{′} )$$

In some embodiments, reliability scores of the group of sensors can be calculated such that the more reliable a sensor is, the higher penalty if the measurement by the sensor is far away from the estimated true state of the respective physical process. So here we can allocate positive reliability score to sensors such that a more reliable sensor will receive higher penalty if its measurement is far away from the estimated ground truth of the process states. As a result, a sensor whose measurements are closer to the estimated ground truth will receive higher reliability score.

To solve the constrained optimization problem, we can introduce Lagrange multiplier to transform it to an unconstrained optimization problem:

$${min}_{c , λ} {\sum }_{p ∈ P} {\sum }_{s ∈ {S}_{p}} {c}_{s} {\sum }_{t = 1}^{T} {( {z}_{p}^{t} - {x}_{s}^{t} )}^{2} + {\sum }_{p ∈ P} {\sum }_{m = 1}^{M} {\sum }_{t = 1}^{T} ( 1 - {e}_{p , m}^{t} ) \frac{{\sum }_{s ∈ {S}_{p , m}^{t}} \vert {w}_{p , m , s}^{t} \vert {c}_{s}}{{\sum }_{s ∈ {S}_{p , m}^{t}} \vert {w}_{p , m , s}^{t} \vert} {( {z}_{p}^{t} - {y}_{p , m}^{t} )}^{2} + λ ( {\sum }_{s ∈ S} exp ( - {c}_{s} ) - 1 ) \qquad ( 2 )$$

Here, in equation (2), soft sensors are taken into account. If not, the constrained optimization problem with introducing Lagrange multiplier can be transformed into:

$${min}_{c , λ} {\sum }_{p ∈ P} {\sum }_{s ∈ {S}_{p}} {c}_{s} {\sum }_{t = 1}^{T} {( {z}_{p}^{t} - {x}_{s}^{t} )}^{2} + λ ( {\sum }_{s ∈ S} exp ( - {c}_{s} ) - 1 ) \qquad ( {2}^{′} )$$

Making partial derivative with respect to cₛ be 0, we get:

$${\sum }_{t = 1}^{T} {( {z}_{p}^{t} - {x}_{s}^{t} )}^{2} + {\sum }_{{p}^{′} ∈ P ∖ p} {\sum }_{m = 1}^{M} {\sum }_{t = 1}^{T} ( 1 - {e}_{{p}^{′} , m}^{t} ) \frac{I ( s ∈ {S}_{{p}^{′} , m}^{t} ) \vert {w}_{{p}^{′} , m , s}^{t} \vert}{{\sum }_{{s}^{′} ∈ {S}_{{p}^{′} , m}^{t}} \vert {w}_{{p}^{′} , m , s}^{t} \vert} {( {z}_{{p}^{′}}^{t} - {y}_{{p}^{′} , m}^{t} )}^{2} = λexp ( - {c}_{s} ) \qquad ( 3 )$$

Where I(*) is an indicator function which equals 1 when the condition is satisfied and 0 otherwise. Since Σ_{s∈S} exp(−cₛ)=1, we get:

$$λ = {\sum }_{p ∈ P} {\sum }_{s ∈ {S}_{p}} {\sum }_{t = 1}^{T} {( {z}_{p}^{t} - {x}_{s}^{t} )}^{2} + {\sum }_{p ∈ P} {\sum }_{s ∈ {S}_{p}} {\sum }_{{p}^{′} ∈ P ∖ p} {\sum }_{m = 1}^{M} {\sum }_{t = 1}^{T} ( 1 - {e}_{{p}^{′} , m}^{t} ) \frac{I ( s ∈ {S}_{{p}^{′} , m}^{t} ) \vert {w}_{{p}^{′} , m , s}^{t} \vert}{{\sum }_{{s}^{′} ∈ {S}_{{p}^{′} , m}^{t}} \vert {w}_{{p}^{′} , m , {s}^{′}}^{t} \vert} {( {z}_{{p}^{′}}^{t} - {y}_{{p}^{′} , m}^{t} )}^{2} \qquad ( 4 )$$

By replacing λ back to Equation (3), we finally obtain:

$${c}_{s} = - ln ( \frac{\begin{matrix}{\sum }_{t = 1}^{T} {( {z}_{p}^{t} - {x}_{s}^{t} )}^{2} + {\sum }_{{p}^{′} ∈ P \backslash p} {\sum }_{m = 1}^{M} {\sum }_{t = 1}^{T} ( 1 - {e}_{{p}^{′} , m}^{t} ) \\ \frac{I ( s ∈ {S}_{{p}^{′} , m}^{t} ) \vert {w}_{{p}^{′} , m , s}^{t} \vert}{{\sum }_{{s}^{′} ∈ {S}_{{p}^{′} , m}^{t}} \vert {w}_{{p}^{′} , m , {s}^{′}}^{t} \vert} {( {z}_{{p}^{′}}^{t} - {y}_{{p}^{′} , m}^{t} )}^{2}\end{matrix}}{\begin{matrix}{\sum }_{p ∈ P} {\sum }_{s ∈ {S}_{p}} {\sum }_{t = 1}^{T} {( {z}_{p}^{t} - {x}_{s}^{t} )}^{2} + \\ {\sum }_{p ∈ P} {\sum }_{s ∈ {S}_{p}} {\sum }_{{p}^{′} ∈ P \backslash p} {\sum }_{m = 1}^{M} {\sum }_{t = 1}^{T} \\ ( 1 - {e}_{{p}^{′} , m}^{t} ) \frac{I ( s ∈ {S}_{{p}^{′} , m}^{t} ) \vert {w}_{{p}^{′} , m , s}^{t} \vert}{{\sum }_{{s}^{′} ∈ {S}_{{p}^{′} , m}^{t}} \vert {w}_{{p}^{′} , m , {s}^{′}}^{t} \vert} {( {z}_{{p}^{′}}^{t} - {y}_{{p}^{′} , m}^{t} )}^{2}\end{matrix}} ) \qquad ( 5 )$$

S104: estimate true states of the physical processes. In the step S104, true states of the physical processes can be estimated based on the calculated reliability scores such that the real state of a physical process should be closer to measurements by a more reliable sensor.

Here we can assume the reliability score of sensors are known, thus we can utilize the reliability score of sensors to obtain a better estimate of the process states. Optionally, true states of the physical processes can be estimated such that estimated true states of the physical processes monitored by the group of sensors in two consecutive discrete time steps are smooth. Optionally, true states of the physical processes can be calculated out such that they make sum of sensor reliability-weighted distance between estimated true state of a physical process and measurement by the sensor monitoring the physical process in predefined at least one time step and among the physical processes and among the group of sensors is minimum. Optionally, given the reliability score of sensors, we can estimate the ground truth of process state by solving the following optimization problem:

$${min}_{{\{ {z}^{t} \}}_{t = 1}^{T}} {\sum }_{p ∈ P} {\sum }_{s ∈ {S}_{P}} {c}_{s} {\sum }_{t = 1}^{T} {( {z}_{p}^{t} - {x}_{s}^{t} )}^{2} + {\sum }_{p ∈ P} {\sum }_{m = 1}^{M} {\sum }_{t = 1}^{T} ( 1 - {e}_{p , m}^{t} ) \frac{{\sum }_{s ∈ {S}_{p , m}^{t}} \vert {w}_{p , m , s}^{t} \vert {c}_{s}}{{\sum }_{s ∈ {S}_{p , m}^{t}} \vert {w}_{p , m , s}^{t} \vert} {( {z}_{p}^{t} - {y}_{p , m}^{t} )}^{2} + {\sum }_{p ∈ P} {γ}_{p} {\sum }_{t = 2}^{T} {( {z}_{p}^{t} - {z}_{p}^{t - 1} )}^{2} \qquad ( 6 )$$

Where in the above the objective term

$${\sum }_{p ∈ P} {\sum }_{s ∈ {S}_{p}} {c}_{s} {\sum }_{t = 1}^{T} {( {z}_{p}^{t} - {x}_{s}^{t} )}^{2} + {\sum }_{p ∈ P} {\sum }_{m = 1}^{M} {\sum }_{t = 1}^{T} ( 1 - {e}_{p , m}^{t} ) \frac{{\sum }_{s ∈ {S}_{p , m}^{t}} \vert {w}_{p , m , s}^{t} \vert {c}_{s}}{{\sum }_{s ∈ {S}_{p , m}^{t}} \vert {w}_{p , m , s}^{t} \vert} {( {z}_{p}^{t} - {y}_{p , m}^{t} )}^{2}$$

seeks to have estimated process states which are closer to the measurements from more reliable sensors; the other objective term Σ_{p∈P}γₚΣₜ₌₂^{T}(zₚ^{t}−zₚ^{t-1})² is a smoothing factor enforcing the smoothness of estimated process states, and γₚ is a user-defined hyperparameter which controls the strengthen of the enforcement for process p. Note that here we use a simple smoothing factor as an illustration which lets two consecutive process states not far away from each other. In principle, other more complicated smoothing factors such as higher-order smoothing factors can also be applied in our context.

Since the optimization problem in Equation (6) is convex, making derivatives with respect to zₚ^{t} be 0, then {z^{t}}ₜ₌₁^{T} takes the solution of the following system of linear equations:

$${\sum }_{s ∈ {S}_{p}} {c}_{s} {z}_{p}^{t} + {\sum }_{m = 1}^{M} ( 1 - {e}_{p , m}^{t} ) \frac{{\sum }_{s ∈ {S}_{p , m}^{t}} \vert {w}_{p , m , s}^{t} \vert {c}_{s}}{{\sum }_{s ∈ {S}_{p , m}^{t}} \vert {w}_{p , m , s}^{t} \vert} {z}_{p}^{t} + I ( t > 1 ) \cdot {γ}_{p} \cdot ( {z}_{p}^{t} - {z}_{p}^{t - 1} ) + I ( t < T ) \cdot {γ}_{p} \cdot ( {z}_{p}^{t} - {z}_{p}^{t + 1} ) = {\sum }_{s ∈ {S}_{p}} {c}_{s} {x}_{s}^{t} + {\sum }_{m = 1}^{M} ( 1 - {e}_{p , m}^{t} ) \frac{{\sum }_{s ∈ {S}_{p , m}^{t}} \vert {w}_{p , m , s}^{t} \vert {c}_{s}}{{\sum }_{s ∈ {S}_{p , m}^{t}} \vert {w}_{p , m , s}^{t} \vert} {y}_{p}^{t} ∀ p ∈ P , t ∈ [ 1 , T ] \qquad ( 7 )$$

Then repeat above step S103 and S105 until Convergence. Here we can apply coordinate descent (Wright, Stephen J. “Coordinate descent algorithms.” Mathematical Programming 151.1 (2015): 3-34) to iteratively update the reliability score of sensors and the estimated truth states of physical processes until convergence. The convergence criterion is based on the Euclidean distance between the estimated truth states of the physical process in two consecutive iterations, thus is defined as follows:

∥{z^{t}}ₜ₌₁^{T}(N)−{z^{t}}ₜ₌₁^{T}(N−1)∥<ϵ (8)

Where {z^{t}}ₜ₌₁^{T}(N) denotes the estimated truth states of the physical process after Nth iteration, ϵ is a user-defined threshold value.

### The Real-Time Evaluation Period

Sensor reliability score calculation and true process state estimation in the warm-up period requires to iteratively solving a system of linear equations in Equation (7) until convergence. Here, referring to FIG. 2, the other method for sensor measurements processing will be introduced, providing an efficient approach for real-time sensor fusion and reliability score calculation.

Concretely, we show how to conduct real-time sensor fusion and reliability monitoring by solving two simple closed form expressions as follows:

S201: measurements collection. In the step of S201, measurements by the group of sensors are collected.

S202: reliability scores acquisition. In the step of S202, reliability scores of the group of sensors are acquired. Optionally, the reliability scores can be pre-set by engineers, can be received from other systems, or can be acquired through above warm-up period. After the warm-up period, we believe that the derived reliability scores for sensors are optimal for the next measurement. Thus, when new measurements from sensors are received, we can first use the reliability scores to do sensor fusion, then the reliability scores for sensors are dynamically updated by keeping a sliding window during which we believe that the latest sensor reliability scores are reflected.

In some embodiments, in the step S201, measurements by a group of sensors are collected at time step t, and reliability scores of the group of sensors are calculated based on: measurements by the group of sensors got at each time step from t−L to t, and estimated true states of the physical processes at each time step from t−L to t.

S202′: soft sensors construction. This step is optional, in the step of S202′, for each physical process, at least one soft sensor can be constructed by calculating measurement by a soft sensor based on measurement by at least one sensor other than the sensor monitoring the physical process in the group of sensors (here, we call them “explanatory sensors”), to enlarge the group of sensors. Similar to above step S102′, by utilizing correlation between the states of multiple physical processes to enhance the inference of sensor reliability scores and the estimation of truth states of physical processes.

In some embodiments, the step S202′ can be executed before the step S202, simultaneously with the step S202, or after the step S202. However, it should be after the step S201, for calculating soft sensor measurements based on physical sensors' measurements, and it should be before the step S203, for true states of the physical processes may be estimated based on soft sensors measurements got in the step S203.

Assume that in the step S201, measurements by the group of sensors are collected at time step t, At the same time step t, we can construct soft sensors using random local linear regression according to measurements got in the step S201 and estimated true states of the physical processes in time steps [1,t−1].

S203: sensor fusion. In the step S203, we conduct sensor fusion to estimate the true state of the physical processes. The sensor fusion can be conducted such that a true state of a physical process should be closer to the measurements by sensors with higher reliability scores; and estimated true states of the physical processes monitored by the group of sensors in two consecutive discrete time steps are smooth.

In some embodiments, the sensor fusion can be conducted at time t by solving:

$${min}_{{z}^{t}} {\sum }_{p ∈ P} {\sum }_{s ∈ {S}_{p}} {{c}_{s}^{t - 1} ( {z}_{p}^{t} - {x}_{s}^{t} )}^{2} + {\sum }_{p ∈ P} {\sum }_{m = 1}^{M} ( 1 - {e}_{p , m}^{t} ) \frac{{\sum }_{s ∈ {S}_{p , m}^{t}} \vert {w}_{p , m , s}^{t} \vert {c}_{s}^{t - 1}}{{\sum }_{s ∈ {S}_{p , m}^{t}} \vert {w}_{p , m , s}^{t} \vert} {( {z}_{p}^{t} - {y}_{p , m}^{t} )}^{2} + {\sum }_{p ∈ P} {γ}_{p} {\sum }_{t = 2}^{T} {( {z}_{p}^{t} - {z}_{p}^{t - 1} )}^{2} \qquad ( 9 )$$

Where zₚ^{t-1} and cₛ^{t-1} are treated as constants that have been calculated in the previous time step. The intuition behind the above equation is that at a specific time step, the truth process state should be closer to the measurement from sensors with higher reliability scores, and also not far away from the previous truth state. Since zₚ^{t-1} and cₛ^{t-1} are known, taking derivative with respect to zₚ^{t} be 0, we get a closed form solution:

$${z}_{p}^{t} = \frac{{\sum }_{s ∈ {S}_{p}} {c}_{s}^{t - 1} {x}_{s}^{t} + {\sum }_{m = 1}^{M} ( 1 - {e}_{p , m}^{t} ) \frac{{\sum }_{s ∈ {S}_{p , m}^{t}} \vert {w}_{p , m , s}^{t} \vert {c}_{s}^{t - 1}}{{\sum }_{s ∈ {S}_{p , m}^{t}} \vert {w}_{p , m , s}^{t} \vert} {y}_{p}^{t} {γ}_{p} {z}_{p}^{t - 1}}{{\sum }_{s ∈ {S}_{p}} {c}_{s}^{t - 1} + {\sum }_{m = 1}^{M} ( 1 - {e}_{p , m}^{t} ) \frac{{\sum }_{s ∈ {S}_{p , m}^{t}} \vert {w}_{p , m , s}^{t} \vert {c}_{s}^{t - 1}}{{\sum }_{s ∈ {S}_{p , m}^{t}} \vert {w}_{p , m , s}^{t} \vert} + {γ}_{p}} \qquad ( 10 )$$

S204: update reliability score. In the step of S204, reliability scores of sensors can be updated to implement Real-time reliability monitoring.

Taking an example, At time step t, let L be the sliding window based on which the reliability score of sensors are calculated, we can dynamically update the reliability score of each sensor based on the sensor measurements observed and the fused results during the sliding window by the following formula:

$${c}_{s}^{t} = - ln ( \frac{\begin{matrix}{\sum }_{{t}^{′} = t - L}^{t} {( {z}_{p}^{{t}^{′}} - {x}_{s}^{{t}^{′}} )}^{2} + {\sum }_{{p}^{′} ∈ P \backslash p} {\sum }_{m = 1}^{M} {\sum }_{{t}^{′} = t - L}^{t} \\ ( 1 - {e}_{{p}^{′} , m}^{t} ) \frac{I ( s ∈ {s}_{{p}^{′} , m}^{{t}^{′}} ) \vert {w}_{{p}^{′} , m , s}^{{t}^{′}} \vert}{{\sum }_{{s}^{′} ∈ {S}_{{p}^{′} , m}^{{t}^{′}}} \vert {w}_{{p}^{′} , m , s}^{{t}^{′}} \vert} {( {z}_{{p}^{′}}^{{t}^{′}} - {y}_{{p}^{′} , m}^{{t}^{′}} )}^{2}\end{matrix}}{\begin{matrix}{\sum }_{p ∈ P} {\sum }_{s ∈ {S}_{p}} {\sum }_{{t}^{′} = t - L}^{t} {( {z}_{p}^{{t}^{′}} - {x}_{s}^{{t}^{′}} )}^{2} \\ {\sum }_{p ∈ P} {\sum }_{s ∈ {S}_{p}} {\sum }_{{p}^{′} ∈ P \backslash p} {\sum }_{m = 1}^{M} {\sum }_{{t}^{′} = t - L}^{t} \\ ( 1 - {e}_{{p}^{′} , m}^{t} ) \frac{I ( s ∈ {s}_{{p}^{′} , m}^{{t}^{′}} ) \vert {w}_{{p}^{′} , m , s}^{{t}^{′}} \vert}{{\sum }_{{s}^{′} ∈ {S}_{{p}^{′} , m}^{{t}^{′}}} \vert {w}_{{p}^{′} , m , s}^{{t}^{′}} \vert} {( {z}_{{p}^{′}}^{{t}^{′}} - {y}_{{p}^{′} , m}^{{t}^{′}} )}^{2}\end{matrix}} ) \qquad ( 11 )$$

### Apparatus

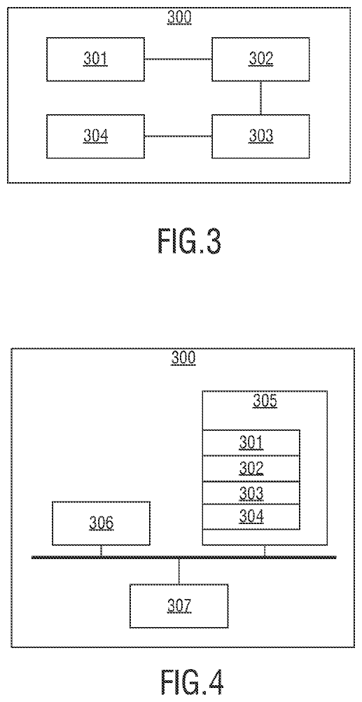

FIG. 3 and FIG. 4 are block diagrams depicting apparatuses for sensor measurement processing incorporating teachings of the present disclosure. Referring to FIG. 3, an apparatus 300 which can execute the above method 100 includes: a measurement module 301, configured to get measurements by a group of sensors, wherein different sensors monitor different physical processes; an estimation module 302, configured to estimate based on the measurements, initial true states of the physical processes monitored by the group of sensors; and a calculation module 303, configured to repeat following steps until convergence: calculate, based on the estimated true states of the physical processes, reliability scores of the group of sensors wherein the higher the score is, the more reliable a sensor is, such that a more reliable sensor should be more likely to provide measurements which are closer to real state of the physical process monitored by the sensor; and estimate, based on the calculated reliability scores, true states of the physical processes, such that the real state of a physical process should be closer to measurements by a more reliable sensor.

In some embodiments, the apparatus 300 can further include a construction module 304, configured to before the calculation module 303 repeats until convergence, construct, for each of the physical processes, at least one soft sensor by calculating measurement by a soft sensor based on measurement by at least one sensor other than the sensor monitoring the physical process in the group of sensors, to enlarge the group of sensors.

In some embodiments, the calculation module 303 can be further configured to calculate reliability scores of the group of sensors, such that the more reliable a sensor is, the higher penalty if the measurement by the sensor is far away from the estimated true state of the respective physical process.

In some embodiments, the calculation module 303 can be further configured to calculate out reliability scores of the group of sensors which make sum of differences between estimated true state of a physical process and measurement by the sensor monitoring the physical process in predefined at least one time step and among the physical processes and among the group of sensors is minimum.

In some embodiments, the calculation module 303 is further configured to calculate out true states of the physical processes which make sum of differences between estimated true state of a physical process and measurement by the sensor monitoring the physical process in predefined at least one time step and among the physical processes and among the group of sensors is minimum.

In some embodiments, the calculation module 303 can be further configured to estimate true states of the physical processes such that estimated true states of the physical processes monitored by the group of sensors in two consecutive discrete time steps are smooth. Other embodiments of the apparatus 300 can be referred to above method 100.

Referring to FIG. 4, another embodiment of the apparatus 300 is depicted. It can include: at least one memory 305, configured to store instructions; and at least one processor 306, coupled to the at least one memory 305, and upon execution of the executable instructions, configured to execute method 100.

In some embodiments, the apparatus 300 may also include I/O interfaces 307, configured to interface with external devices. The at least one processor 306, the at least one memory 305 and I/O interfaces can be connected via a bus, or connected directly to each other. In some embodiments, above mentioned modules 301˜304 can be software modules including instructions which are stored in the at least one memory 305, when executed by the at least one processor 306, execute the method 100.

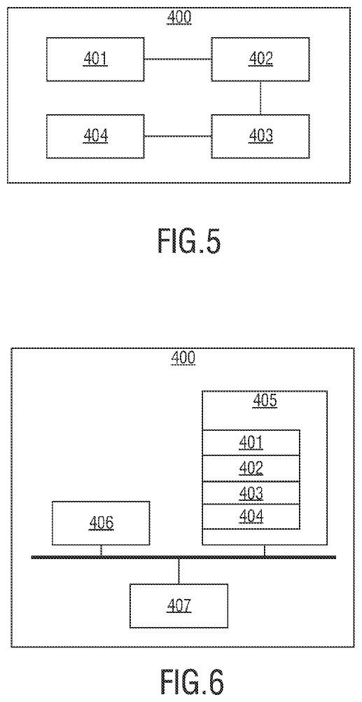

FIG. 5 and FIG. 6 are block diagrams depicting apparatuses for sensor measurement processing incorporating teachings of the present disclosure. Referring to FIG. 5, an apparatus 400 which can execute the above method 200 includes: a measurement module 401, configured to get measurements by a group of sensors, wherein different sensors monitor different physical processes; an acquisition module 402, configured to acquire reliability scores of the group of sensors; and a fusion module 403, configured to estimate, based on the acquired reliability scores, true states of the physical processes monitored by the group of sensors such that a true state of a physical process should be closer to the measurements by sensors with higher reliability scores.

In some embodiments, the fusion module 403 can be further configured to conduct the sensor fusion such that estimated true states of the physical processes monitored by the group of sensors in two consecutive discrete time steps are smooth.

In some embodiments, the measurement module 401 can be further configured to get at time step t, measurements by a group of sensors; the acquisition module 402 can be further configured to calculate reliability scores of the group of sensors based on: measurements by the group of sensors got at each time step from t−L to t, and estimated true states of the physical at each time step from t−L to t.

In some embodiments, the apparatus 400 can further include a construction module 404 configured to, before the acquisition module 402 acquires reliability scores of the group of sensors, construct, for each physical process, at least one soft sensor by calculating measurement by a soft sensor based on measurement by at least one sensor other than the sensor monitoring the physical process in the group of sensors, to enlarge the group of sensors.

Referring to FIG. 6, another embodiment of the apparatus 400 is depicted. It can include: at least one memory 405, configured to store instructions; and at least one processor 406, coupled to the at least one memory 405, and upon execution of the executable instructions, configured to execute method 200.

In some embodiments, the apparatus 400 may also include I/O interfaces 407, configured to interface with external devices. The at least one processor 406, the at least one memory 405 and I/O interfaces can be connected via a bus, or connected directly to each other. In some embodiments, above mentioned modules 401˜404 can be software modules including instructions which are stored in the at least one memory 405, when executed by the at least one processor 406, execute the method 200.

### Experiment

We use our approach to monitor the reliability of sensors deployed for urban air pollution monitoring and fuse sensor measurements for more reliable pollution report. Experiment shows that our method can timely detect faulty sensors with low reliability scores and provide more accurate measurements.

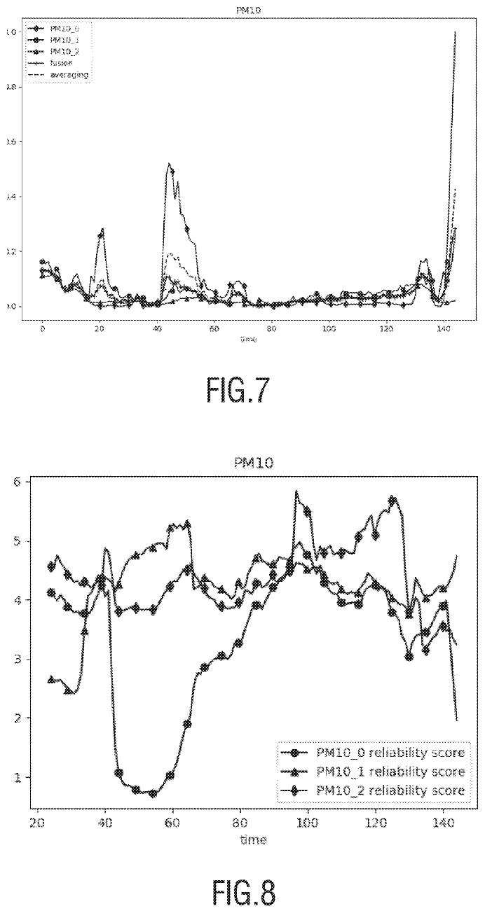

Taking FIG. 7 an FIG. 8 as an example. PM10_0, PM10_1 and PM10_2 are three sensors for measurement of PM10 (particulate matter 10). In FIG. 7, we can see that the sensor PM10_0 reports abnormal PM10 measurements during the time interval around 40 to 60, this is caused by a physical fault of the sensor which is confirmed by the system operator. From FIG. 7, we can observe that our proposed fusion method reports much more reliable PM10 measurements than taking the averaging between the three redundant sensors. In FIG. 8, we can see that our method also timely identified that the sensor PM10_0 has much lower reliability score than other two sensors during the time interval around 40 to 60.

Various methods, apparatuses, and computer-readable storage media for sensor measurement processing are described herein. Based on sensor measurements, reliability scores of sensors can be calculated. By giving less weights to unreliable sensors, accuracy of estimation of true states of monitored physical processes can be improved; and comparing to Kalman filtering-based methods, the dynamic model of the underlying physical process is not necessarily known to conduct measurements fusion, which makes our solution much more applicable in practical scenarios.

Firstly, our approach is purely data-driven and it does not require the dynamic model of the underlying physical process to be known. We treat the evaluation of sensor reliability scores and sensor fusion as an optimization problem based on the principle that more reliability sensors should be more likely to provide sensor measurements closer to the true states of the physical processes. Using the optimization framework we proposed, our approach does not necessarily need any Kalman filtering-based algorithms. As a result, our approach not only provides accurate estimates of the truth process states, but also becomes more generalizable and applicable. Also, to utilize the correlation between the states of multiple physical processes to enhance the inference of sensor reliability scores and the estimation of truth states of physical processes, for each physical process, besides the physical sensors, we further construct soft sensors for monitoring its state at each time step by random local regression.

Secondly, we proposed a dynamic approach to monitor sensor reliability in real time. we use a sliding window based on which to efficiently update the sensor reliability score. As a result, our approach can capture evolving sensor reliability scores. Furthermore, the fused measurements using our approach are more accurate than the commonly used averaging method as illustrated in our experiment.

While the present techniques have been described in detail with reference to certain embodiments, it should be appreciated that the present technique is not limited to those precise embodiments. Rather, in view of the present disclosure which describes exemplary modes for practicing the teachings herein, many modifications and variations would present themselves, to those skilled in the art without departing from the scope and spirit of this disclosure. All changes, modifications, and variations coming within the meaning and range of equivalency of the claims are to be considered within their scope.

What is claimed is:

1. A method for sensor measurement processing, the method comprising:
collecting measurements from a group of sensors, wherein different sensors in the group monitor different physical processes;
estimating, based on the measurements, initial true states of the various physical processes; and
repeating until convergence:
calculating, based on the estimated true states of the physical processes, reliability scores of each sensor of the group of sensors, wherein a higher score represents a more reliable sensor measurement; and
estimating, based on the calculated reliability scores, true states of the various physical processes.

2. The method according to claim 1, further comprising, before repeating until convergence,
constructing, for each of the physical processes, a respective soft sensor by calculating measurement based on measurement by an additional sensor other than the sensor monitoring the physical process in the group of sensors, to enlarge the group of sensors.

3. The method according to claim 2, wherein calculating reliability scores for the individual sensors of the group of sensors comprises
calculating reliability scores of each sensor in the group of sensors, such that the more reliable a sensor is, the higher penalty if the measurement by the sensor is far away from the estimated true state of the respective physical process.

4. The method according to claim 1, wherein calculating reliability scores of a sensor comprises
calculating reliability scores of each sensor in the group of sensors to provide a sum of sensor reliability-weighted distance between estimated true state of a physical process and measurement by the sensor monitoring the physical process in a predefined time step and among the physical processes and among the group of sensors is minimum.

5. The method according to claim 1, wherein estimating true states of physical processes monitored by the group of sensors comprises
calculating true states of the physical processes which make sum of sensor reliability-weighted distance between estimated true state of a physical process and measurement by the sensor monitoring the physical process in predefined at least one time step and among the physical processes and among the group of sensors is minimum.

6. The method according to claim 1, wherein estimating true states of the physical processes comprises
estimating true states of the physical processes such that estimated true states of the physical processes monitored by the group of sensors in two consecutive discrete time steps are smooth.

7. A method for sensor measurement processing, the method comprising:
gathering measurements from a group of sensors, wherein different sensors monitor different physical processes;
acquiring reliability scores for each sensor in the group of sensors;
conducting sensor fusion based on the acquired reliability scores, to estimate true states of the physical processes monitored by the group of sensors such that
a true state of a physical process should be closer to the measurements by sensors with higher reliability scores.

8. The method according to claim 7, wherein conducting sensor fusion based on the acquired reliability scores to estimate true states of the physical processes monitored by the group of sensors comprises
conducting sensor fusion such that estimated true states of the physical processes monitored by the group of sensors in two consecutive discrete time steps are smooth.

9. The method according to claim 7, wherein:
gathering measurements by the sensors comprises getting at time step t, measurements by the group of sensors; and
acquiring reliability scores of the sensors comprises calculating reliability scores of the sensors based on:
measurements by the group of sensors got at each time step from t−L to t, and
estimated true states of the physical processes at each time step from t−L to t.

10. The method according to claim 7, further comprising, before repeating until convergence,
constructing for each physical process a soft sensor by calculating measurement by a soft sensor based on measurement by at least one sensor other than the sensor monitoring the physical process in the group of sensors to enlarge the group of sensors.

11. An apparatus for sensor measurements processing, comprising:
a measurement module configured to gather measurements by each sensor in a group of sensors, wherein different sensors monitor different physical processes;
an estimation module configured to estimate based on the measurements initial true states of the physical processes monitored by the group of sensors; and
a calculation module configured to repeat until convergence:
calculating, based on the estimated true states of the physical processes, reliability scores of the group of sensors wherein the higher the score is, the more reliable a sensor is, such that a more reliable sensor should be more likely to provide measurements which are closer to real state of the physical process monitored by the sensor; and
estimating, based on the calculated reliability scores, true states of the physical processes, such that the real state of a physical process should be closer to measurements by a more reliable sensor.

12. The apparatus according to claim 11, further comprising a construction module configured to before the calculation module repeats until convergence, construct, for each of the physical processes, a soft sensor by calculating measurement by a soft sensor based on measurement by at least one sensor other than the sensor monitoring the physical process in the group of sensors, to enlarge the group of sensors.

13. The apparatus according to claim 12, wherein the calculation module is further configured to calculate reliability scores of the group of sensors, such that the more reliable a sensor is, the higher penalty if the measurement by the sensor is far away from the estimated true state of the respective physical process.

14. The apparatus according to claim 11, wherein the calculation module is further configured to
calculate out reliability scores of the group of sensors which make sum of differences between estimated true state of a physical process and measurement by the sensor monitoring the physical process in predefined at least one time step and among the physical processes and among the group of sensors is minimum.

15. The apparatus according to claim 11, wherein the calculation module is further configured to
calculate out true states of the physical processes which make sum of differences between estimated true state of a physical process and measurement by the sensor monitoring the physical process in predefined at least one time step and among the physical processes and among the group of sensors is minimum.

16. The apparatus according to claim 11, wherein the calculation module is further configured to
estimate true states of the physical processes such that estimated true states of the physical processes monitored by the group of sensors in two consecutive discrete time steps are smooth.

17. (canceled)

18. An apparatus for sensor measurement processing, the apparatus comprising:
a measurement module configured to get measurements by a group of sensors, wherein different sensors monitor different physical processes;
an acquisition module configured to acquire reliability scores of the group of sensors; and
an fusion module configured to estimate, based on the acquired reliability scores, true states of the physical processes monitored by the group of sensors such that
a true state of a physical process should be closer to the measurements by sensors with higher reliability scores.

19. The apparatus according to claim 18, wherein the fusion module is further configured to conduct the sensor fusion such that estimated true states of the physical processes monitored by the group of sensors in two consecutive discrete time steps are smooth.

20. The apparatus according to claim 18, wherein:
the measurement module is further configured to get at time step t, measurements by a group of sensors; and
the acquisition module is further configured to calculate reliability scores of the group of sensors based on:
measurements by the group of sensors got at each time step from t−L to t, and
estimated true states of the physical at each time step from t−L to t.

21. The apparatus according to claim 18, further comprising a construction module configured to, before the acquisition module acquires reliability scores of the group of sensors, construct, for each physical process, a soft sensor by calculating measurement by a soft sensor based on measurement by at least one sensor other than the sensor monitoring the physical process in the group of sensors, to enlarge the group of sensors.

22-23. (canceled)
